(19) United States
(12) Patent Application Publication
(10) Pub. No.: US 2006/0191638 A1
(43) Pub. Date: Aug. 31, 2006

(54) ETCHING APPARATUS FOR SEMICONDUCTOR FABRICATION

(75) Inventors: Timothy J. Dalton, Ridgefield, CT (US); Emily F. Gallagher, Burlington, VT (US); Louis M. Kindt, Milton, VT (US); Carey W. Thiel, Williston, VT (US); Andrew J. Watts, Essex, VT (US)

Correspondence Address: SCHMEISER, OLSEN & WATTS, 22 CENTURY HILL DRIVE, SUITE 302, LATHAM, NY, 12110, US

(73) Assignee: INTERNATIONAL BUSINESS MACHINES CORPORATION, Armonk, NY (US)

(21) Appl. No.: 10/906,627

(22) Filed: Feb. 28, 2005

(51) Int. Cl. C23F 1/00; C23C 16/00

(52) U.S. Cl. 156/345.43; 118/723 E

(57) ABSTRACT

An apparatus (and method for operating the same) which allows etching different substrate etch areas of a substrate having different pattern densities at essentially the same etch rate. The apparatus includes (a) a chamber; (b) an anode and a cathode in the chamber; and (c) a bias power system coupled to the cathode, wherein the cathode includes multiple cathode segments. The operation method includes the steps of: (i) placing a substrate to be etched between the anode and cathode, wherein the substrate includes N substrate etch areas, and the N substrate etch areas are directly above the N cathode segments; (ii) determining N bias powers which, when being applied to the N cathode segments during an etching of the substrate, will result in essentially a same etch rate for the N substrate etch areas; and (iii) using the bias power system to apply the N bias powers the N cathode segments.

### BACKGROUND OF THE INVENTION

1. Technical Field

The present invention relates to etching tools for semiconductor and photomask fabrication, and more specifically, to etching tools for dry etching.

2. Related Art

A conventional fabrication process usually involves the step of dry etching a top surface of a substrate (e.g., a wafer or a photomask). Typically, first, a photoresist layer or any useful masking layer can be applied to the substrate. Then, the mask layer can be patterned using a photolithography process so that only areas of substrate that need to be etched are exposed from underneath the masking layer. The other areas of the substrate that need to be kept intact are covered by the patterned masking layer. Next, the substrate (with the patterned masking layer on top) can be placed on the cathode of an etching chamber. A radio frequency (RF, typically at a frequency of 0.1 MHz to 2.5 GHz) electrical power generator can be applied to the anode of the chamber so as to generate a plasma in the chamber. As a result, etchants generated within the plasma chemically react with the exposed material of the substrate surface to create a volatile product that can easily be removed by the etch system. Thus the pattern of the patterned masking layer is transferred to the substrate surface. Additional RF electrical energy may be coupled into the cathode to both increase the rate of etch processing and to provide directionality to the reactive species generated within the plasma.

However, different substrate areas facing the anode may be etched at different etch rates and with different profiles because these different substrate areas may have different pattern densities. The pattern density of a substrate can be defined as the percentage of the exposed-to-atmosphere surface of the substrate. For example, assume a 1 cm² substrate consists of 0.4 cm² being covered by the patterned mask layer and 0.6 cm² being exposed to the atmosphere. As the result, the pattern density of the substrate to be etched is 60%. If a substrate consists of a first substrate etch area with a higher pattern density than a second substrate etch area, then the first substrate etch area consumes etchants at a higher rate than the second substrate etch area. As a result, fewer etchants are available for further etching in the first substrate etch area than in the second substrate etch area. Therefore, the etch rate (and other properties such as feature profile) of the first substrate etch area is less than the etch rate of the second substrate etch area.

As a result, there is a need for a new apparatus (and method for operating the same) which allows etching different substrate etch areas having different pattern densities at essentially the same etch rate.

### SUMMARY OF THE INVENTION

The present invention provides an apparatus, comprising (a) a chamber; (b) an anode and a cathode positioned in the chamber; and (c) a bias power system coupled to the cathode, wherein the cathode comprises N cathode segments electrically insulated from each other, N being an integer greater than 1, and wherein the bias power system is configured to apply N bias powers one-to-one to the N cathode segments.

The present invention also provides an apparatus operating method, comprising the steps of (a) providing (i) a chamber, (ii) an anode and a cathode positioned in the chamber, and (iii) a bias power system coupled to the cathode, wherein the cathode comprises N cathode segments electrically insulated from each other, N being an integer greater than 1; (b) placing a substrate to be etched between the anode and the cathode, wherein the structure comprises N substrate etch areas facing the anode, and wherein the N substrate etch areas are directly above the N cathode segments in a reference direction and match in size and shape with the N cathode segments, wherein the reference direction is essentially perpendicular to a surface of the anode facing the cathode; (c) determining N bias powers which, when being applied one-to-one to the N cathode segments during an etching of the substrate, will result in essentially a same etch rate for the N substrate etch areas; and (d) using the bias power system to apply the N bias powers one-to-one to the N cathode segments during the etching of the substrate.

The present invention also provides an apparatus operating method, comprising the steps of (a) providing (i) a chamber, (ii) an anode and a cathode positioned in the chamber, and (iii) a bias power system coupled to the cathode, wherein the cathode comprises N cathode segments electrically insulated from each other, N being an integer greater than 1; (b) placing a substrate to be etched between the anode and the cathode, wherein the substrate comprises N substrate etch areas facing the anode, and wherein the N substrate etch areas are directly above the N cathode segments in a reference direction and match in size and shape with the N cathode segments, wherein the reference direction is essentially perpendicular to a surface of the anode facing the cathode; (c) applying a plasma generation power to the anode sufficiently to generate a plasma in the chamber; and (d) applying N bias powers one-to-one to the N cathode segments

The present invention also provides a new apparatus (and method for operating the same) which allows etching different substrate etch areas having different pattern densities at essentially the same etch rate.

### BRIEF DESCRIPTION OF THE DRAWINGS

FIG. 1 illustrates an apparatus, in accordance with embodiments of the present invention.

FIG. 2 illustrates a plasma generation power system of the apparatus of FIG. 1, in accordance with embodiments of the present invention.

FIGS. 3A-3E illustrate different embodiments of a cathode of the apparatus of FIG. 1.

FIGS. 4A-4B illustrate different embodiments of a bias power system of the apparatus of FIG. 1.

FIG. 5 illustrates a bias power subsystem that can be used in the embodiments of FIGS. 4A-4B, in accordance with embodiments of the present invention.

### DETAILED DESCRIPTION OF THE INVENTION

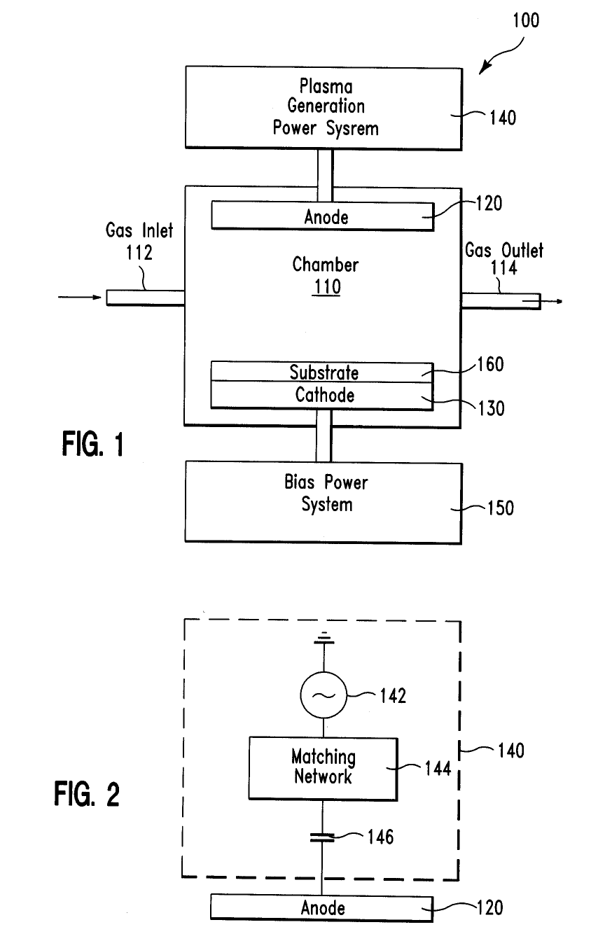

FIG. 1 illustrates an apparatus 100, in accordance with embodiments of the present invention. Illustratively, the apparatus 100 can comprise a chamber 110, an anode 120 and a cathode 130 in the chamber 110. The chamber 110 can include a gas inlet 112 and a gas outlet 114. The gas inlet 112 can be used to receive gas species into the chamber 110. The gas outlet 114 can be used to lead gases out of the chamber 110. The depiction and location of gas inlet 112 and outlet 114 is purely representational in FIG. 1. An actual inlet and outlet may consist of a plurality of actual openings. Additionally, it is well known to one skilled in the arts that the location of the inlet and outlet can be placed at different locations within the chamber to modify the efficiency of gas flow within the chamber and consequently the gas's influence on a substrate placed within the chamber.

The anode 120 can be coupled to a plasma generation power system 140. In one embodiment, the plasma generation power system 140 can be configured to generate a plasma generation power (e.g., a radio frequency voltage) to the anode 120 so as to create a plasma from the gas species in the chamber 110. The plasma contains etchants necessary for substrate etching.

The cathode 130 can comprise N cathode segments (not shown, but details of these cathode segments will be described below) matching in size and shape with N substrate etch areas (facing the anode 120) of a substrate 160 placed on the cathode 130, wherein N is an integer greater than one. The N cathode segments can be electrically insulated from each other. The cathode 130 can be coupled to a bias power system 150 which, during the etching of the substrate 160, can be configured to generate N bias powers (e.g., each can be a radio frequency voltage) to the N cathode segments of the cathode 130. By adjusting a bias power to a cathode segment, the bias power system 150 can adjust the energy of the ions bombarding the substrate etch area of the substrate 160 directly above the cathode segment. As a result, by adjusting the bias power to the cathode segment, the bias power system 150 can adjust the etch rate for the substrate etch area directly above the cathode segment.

In one embodiment, the N bias powers can be individually assigned by prior assumptions or by theoretical calculations such that when the N bias powers are applied one-to-one to the N cathode segments during the dry etching of the substrate 160, the N substrate etch areas experience essentially the same etch rate.

In another embodiment, the N bias powers can be individually assigned by using a “design of experiments” methodology or a simpler trial-and-error methodology. More specifically, multiple substrates (not shown) identical to the substrate 160 can be etched one after another using essentially the same etching settings (i.e. pressure, etchants, gas flow rate, etc.) while individually varying the N bias powers. The resultant substrates after etching can be examined to determine the etch rate uniformity across the substrate. Then the N bias powers can be individually adjusted until the N substrate etch areas experience essentially the same etch rate. In other words, the results of the etching of a substrate can be used to determine new bias powers for etching the next substrate, and so on until the etch result is satisfactory (i.e., essentially the same etch rate for all the N substrate etch areas).

Alternatively, the N bias powers can be individually determined by using a database containing correlations between bias powers, pattern densities, and etch rates. In one embodiment, the database is built from empirical data. More specifically, experiments (i.e., etching) can be carried out in a predetermined etch setting (i.e., gas flow rate, etchants, pressures, etc.) for different pattern densities and different applied bias powers, and the resulting etch rates can be recorded and entered into the database. To achieve essentially the same etch rate for all N substrate etch areas with N given pattern densities in the predetermined etch setting, the N bias powers can be individually determined using the database.

FIG. 2 illustrates one embodiment of the plasma generation power system 140 of the apparatus 100 of FIG. 1, in accordance with embodiments of the present invention. Illustratively, the plasma generation power system 140 can comprise (i) an RF (radio frequency) power source 142, a matching network 144 coupled to the RF power source 142, and, for a capacitively-coupled plasma source, a blocking capacitor 146 coupling the matching network 144 to the anode 120. For inductively-coupled plasma sources, blocking capacitor 146 is optional. The RF power source 142 produces an electrical voltage of the desired frequency. The matching network 144 matches the variable impedance of the plasma to the desired fixed impedance of the RF power source 142 so as to maximize the transfer of electrical power from RF power source 142 into the chamber 110. Blocking capacitor 146 serves to prevent the flow of direct current (DC) power from RF power source 142 into chamber 110, only allowing the passage of alternating current (AC) power.

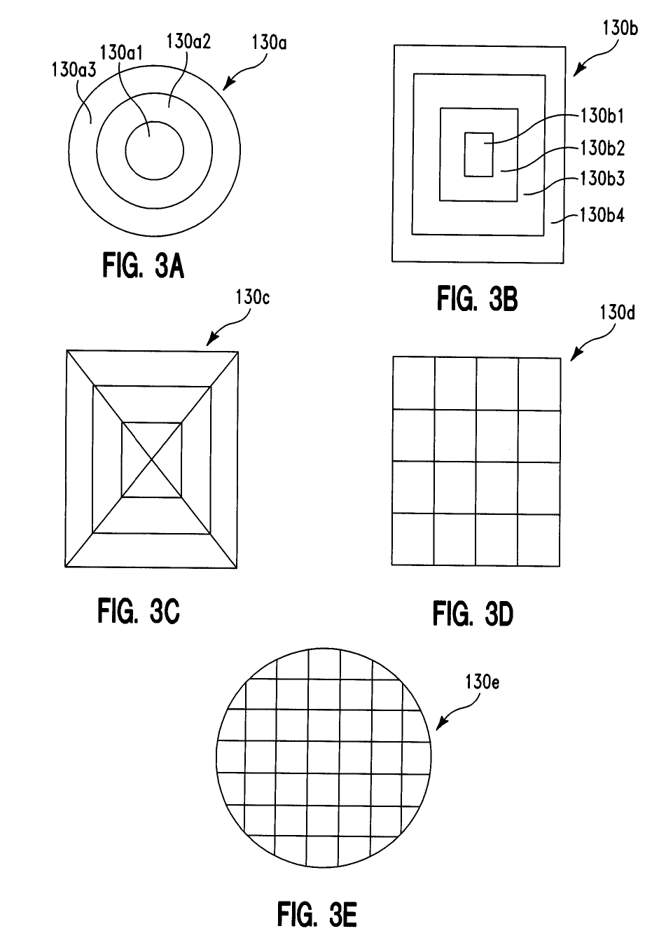

FIGS. 3A-3E illustrate different embodiments 130a, 130b, 130c, 130d, and 130e, respectively, of the cathode 130 of FIG. 1. More specifically, FIG. 3A shows a top-down view of the cathode 130a. The cathode 130a can have the circular shape and can comprise three cathode segments 130a1, 130a2, and 130a3. In one embodiment, the cathode segments 130a1, 130a2, and 130a3 can be electrically insulated from each other. In general, there can be N (N being an integer greater than one) concentric cathode segments having ring form as in FIG. 3A.

FIG. 3B shows a top-down view of the cathode 130b. The cathode 130b can have the rectangular shape and can comprise four (or any integer number greater than one) cathode segments 130b1, 130b2, 130b3, and 130b4. The cathode segments 130b1, 130b2, 130b3, and 130b4 can be electrically insulated from each other.

FIG. 3C shows a top-down view of the cathode 130c. The cathode 130b can have the rectangular shape and can comprise 12 (or any integer number multiple of 4 and at least 4) cathode segments of trapezoidal and triangular shapes. The cathode segments of the cathode 130c can be electrically insulated from each other.

FIG. 3D shows a top-down view of the cathode 130d. The cathode 130d can have the rectangular shape and can comprise cathode segments arranged in 4 rows and 4 columns (i.e., 16 cathode segments in total). In general, the number of rows and the number of columns can be any positive integer (but can not be 1 simultaneously) and do not have to be the same. The cathode segments of the cathode 130d can be electrically insulated from each other.

FIG. 3E shows a top-down view of the cathode 130e. The cathode 130e can have the circular shape and can comprise cathode segments arranged in 7 rows and 7 columns (i.e., 49 cathode segments in total). In general, the number of rows and the number of columns can be any positive integer (but can not be 1 simultaneously) and do not have to be the same. The cathode segments of the cathode 130e can be electrically insulated from each other.

In general, the cathode 130 of FIG. 1 can have any shape and can comprise any number (more specifically, any integer greater than 1) of cathode segments. Each of the cathode segments can have any size and shape.

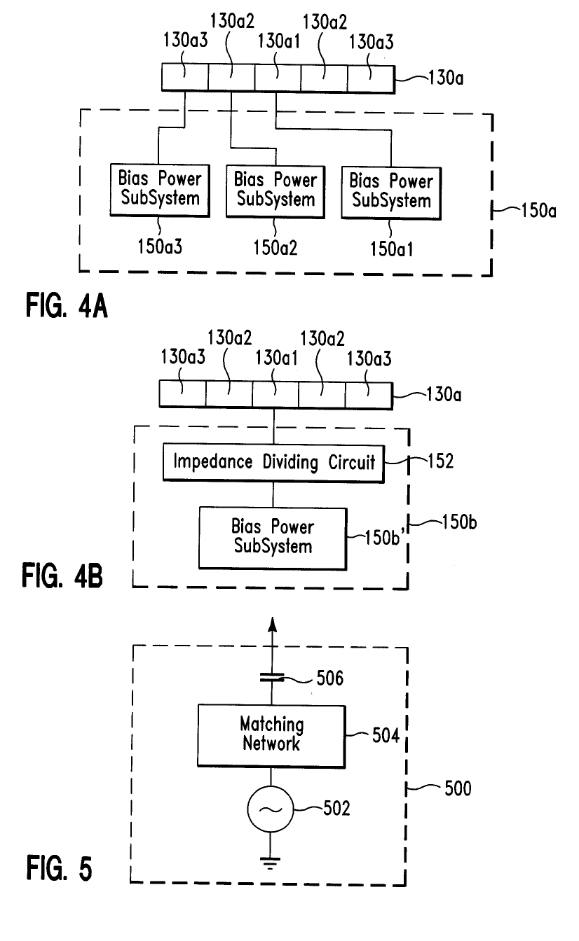

FIGS. 4A-4B illustrate two different embodiments 150a and 150b, respectively, of the bias power system 150 of FIG. 1. More specifically, with reference to FIG. 4A, assume the cathode embodiment 130a of FIG. 3A is used as the cathode 130 of FIG. 1 (in FIG. 4A, a cross-section view of the cathode 130a is shown). Because the cathode 130a has three cathode segments 130a1, 130a2, and 130a3, the bias power system 150a can comprise the same number of (i.e., three) independent bias power subsystems 150a1, 150a2, and 150a3 coupled one-to-one to the cathode segments 130a1, 130a2, and 130a3, respectively. The three bias power subsystems 150a1, 150a2, and 150a3 can be configured to generate three independent bias powers (e.g., radio frequency voltages) one-to-one to the three cathode segments 130a1, 130a2, and 130a3, respectively.

In general, if the cathode 130 of FIG. 1 has M cathode segments (M being an integer greater than 1), then M bias power subsystems similar to the bias power subsystems 150a1, 150a2, and 150a3 of can be used to generate M independent bias powers one-to-one to the M cathode segments.

With reference to FIG. 4B, assume the cathode embodiment 130a of FIG. 3A is again used as the cathode 130 of FIG. 1 (in FIG. 4B, a cross-section view of the cathode 130a is shown). In one embodiment, the bias power system 150b can comprise a bias power subsystem 150b′ and an impedance dividing circuit 152 coupling the bias power subsystem 150b′ to the cathode segments 130a1, 130a2, and 130a3. The bias power subsystem 150b′ can be configured to generate a total bias power to the impedance dividing circuit 152. In response to receiving the total bias power from the bias power subsystem 150b′, the impedance dividing circuit 152 can be configured to generate three different bias powers one-to-one to the three cathode segments 130a1, 130a2, and 130a3. The simplest example of an impedance divider circuit is a voltage divider circuit. In this case, an input voltage is put through two resistors (fixed or variable) in series. The output voltage is taken off between the two resistors. In general, a series of M voltage dividers may be constructed to drive M cathode segments. By applying the same input voltage to each of the M voltage dividers, the output to each of the M cathode segments can be individually adjusted.

FIG. 5 illustrates a bias power subsystem 500 that can be used as the bias power subsystems 150a1, 150a2, and 150a3 of FIG. 4A and the bias power subsystems 150b′ of FIG. 4B. In one embodiment, the bias power subsystem 500 can comprise (i) an RF power source 502, a matching network 504 coupled to the RF power source 502, and, for a capacitively-coupled plasma source, a blocking capacitor 506 coupling the matching network 504 either to the cathode 130a of FIG. 4A or to the impedance dividing circuit 152 of FIG. 4B. Generator 502 produces an electrical voltage at the desired frequency. Matching network 504 matches the variable impedance of the plasma across the substrate 160 (FIG. 1) to the desired fixed impedance of generator 502 so as to maximize the transfer of electrical power from generator 502 into substrate 160 (FIG. 1). Blocking capacitor 506 serves to prevent the flow of direct current (DC) power from generator 502 into substrate 160 and chamber 110 (FIG. 1), only allowing the passage of alternating current (AC) power. Modulation of the output of generator 502 produces a modulation in the bias voltage on substrate 160 (FIG. 1).

In summary, with reference to FIG. 1, by using the N-segment cathode 130, N bias powers can be individually determined such that when these N bias powers are applied to the N cathode segments (not shown), the N substrate etch areas of the substrate 160 directly above the N cathode segments experience essentially the same etch rate. The N bias powers can be individually determined by trials and errors, or alternatively, by using a database built through experiments.

In a similar manner, the present invention can be used to etch a variety of substrates 160 (FIG. 1). For example, the present invention can be used to etch a wafer or a photomask.

While particular embodiments of the present invention have been described herein for purposes of illustration, many modifications and changes will become apparent to those skilled in the art. Accordingly, the appended claims are intended to encompass all such modifications and changes as fall within the true spirit and scope of this invention.

What is claimed is:

1. An apparatus, comprising:
(a) a chamber;
(b) an anode and a cathode positioned in the chamber; and
(c) a bias power system coupled to the cathode,
wherein the cathode comprises N cathode segments electrically insulated from each other, N being an integer greater than 1, and
wherein the bias power system is configured to apply N bias powers one-to-one to the N cathode segments.

2. The apparatus of claim 1, wherein the anode is coupled to a plasma generation power system configured to apply sufficient power to the anode to generate a plasma in the chamber.

3. The apparatus of claim 2, wherein the plasma generation power system comprises:
a radio frequency plasma generation power source; and
a matching network coupled to the radio frequency plasma generation power source and to the anode.

4. The apparatus of claim 1,
wherein the bias power system comprises N bias power subsystems being coupled one-to-one to the N cathode segments, and
wherein the N bias power subsystems are configured to apply the N bias powers one-to-one to the N cathode segments.

5. The apparatus of claim 4, wherein for i=1, 2, . . . , N, an i^{th} bias power subsystem of the N bias power subsystems comprises:
an i^{th} radio frequency bias source; and
an i^{th} matching network coupled to the i^{th} radio frequency bias source and to the i^{th} cathode segment.

6. The apparatus of claim 4, wherein each bias power subsystem of the N bias power subsystems is capable of adjusting the bias power subsystem's generated bias power.

7. The apparatus of claim 1,
wherein the bias power system comprises (i) an impedance dividing circuit coupled to the N cathode segments, and (ii) a bias power subsystem coupled to the impedance dividing circuit, and
wherein in response to receiving a total bias power from the bias power subsystem, the impedance dividing circuit is configured to generate the N bias powers one-to-one to the N cathode segments.

8. The apparatus of claim 7, wherein the bias power subsystem comprises:
a radio frequency bias power source; and
a matching network coupled to the radio frequency bias power source and to the impedance dividing circuit.

9. The apparatus of claim 7, wherein the bias power subsystem is capable of adjusting the bias power subsystem's generated bias power.

10. The apparatus of claim 1, wherein the chamber comprises:
a gas inlet configured to receive first gas species into the chamber; and
a gas outlet configured to exhaust second gas species out of the chamber.

11. An apparatus operating method, comprising the steps of:
(a) providing (i) a chamber, (ii) an anode and a cathode positioned in the chamber, and (iii) a bias power system coupled to the cathode, wherein the cathode comprises N cathode segments electrically insulated from each other, N being an integer greater than 1;
(b) placing a substrate to be etched between the anode and the cathode, wherein the structure comprises N substrate etch areas facing the anode, and wherein the N substrate etch areas are directly above the N cathode segments in a reference direction and match in size and shape with the N cathode segments, wherein the reference direction is essentially perpendicular to a surface of the anode facing the cathode;
(c) determining N bias powers which, when being applied one-to-one to the N cathode segments during an etching of the substrate, will result in essentially a same etch rate for the N substrate etch areas; and
(d) using the bias power system to apply the N bias powers one-to-one to the N cathode segments during the etching of the substrate.

12. The method of claim 11, wherein step (c) is performed using the following steps:
(i) etching a first test substrate using the steps (b) and (d), wherein the N bias powers are predetermined;
(ii) examining the first test substrate after step (i) is performed;
(iii) adjusting the N bias powers based on a result of step (ii); and
(iv) repeating steps (i), (ii) and (iii) for at least one additional test substrate until step (ii) results in essentially the same etch rate for the N substrate etch areas.

13. The method of claim 11, wherein step (c) is performed using the following steps:
determining N pattern densities for the N substrate etch areas; and
using a database to determine the N bias powers based on the N pattern densities,
wherein the database contains correlations between bias powers, pattern densities, and etch rates.

14. The method of claim 13, wherein the correlations between bias powers, pattern densities, and etch rates are determined from empirical data.

15. The method of claim 11, wherein step (d) comprises the step of using N bias power subsystems of the bias power system to apply the N bias powers one-to-one to the N cathode segments, wherein the N bias power subsystems are coupled one-to-one to the N cathode segments.

16. The method of claim 11, wherein step (d) comprises the steps of:
using a bias power subsystem of the bias power system to generate a total bias power to an impedance dividing circuit of the bias power system; and
in response to the impedance dividing circuit receiving the total bias power, using the impedance dividing circuit to generate the N bias powers one-to-one to the N cathode segments.

17. An apparatus operating method, comprising the steps of:
(a) providing (i) a chamber, (ii) an anode and a cathode positioned in the chamber, and (iii) a bias power system coupled to the cathode, wherein the cathode comprises N cathode segments electrically insulated from each other, N being an integer greater than 1;
(b) placing a substrate to be etched between the anode and the cathode, wherein the substrate comprises N substrate etch areas facing the anode, and wherein the N substrate etch areas are directly above the N cathode segments in a reference direction and match in size and shape with the N cathode segments, wherein the reference direction is essentially perpendicular to a surface of the anode facing the cathode;
(c) applying a plasma generation power to the anode sufficiently to generate a plasma in the chamber; and
(d) applying N bias powers one-to-one to the N cathode segments.

18. The method of claim 17,
wherein in step (d), the N bias powers chosen such that N substrate etch areas of the substrate experience essentially a same etch rate.

19. The method of claim 17, wherein step (d) comprises the step of using N bias power subsystems of the bias power system to apply the N bias powers one-to-one to the N cathode segments, wherein the N bias power subsystems are coupled one-to-one to the N cathode segments.

20. The method of claim 17, wherein step (d) comprises the steps of:
using a bias power subsystem of the bias power system to generate a total bias power to an impedance dividing circuit of the bias power system; and
in response to the impedance dividing circuit receiving the total bias power, using the impedance dividing circuit to generate the N bias powers one-to-one to the N cathode segments.
